(19) United States
(12) Patent Application Publication
(10) Pub. No.: US 2024/0008628 A1
(43) Pub. Date: Jan. 11, 2024

(54) MOBILE ENTERTAINMENT APPARATUS

(71) Applicant: Davis McGee, Orlando, FL (US)

(72) Inventor: Davis McGee, Orlando, FL (US)

(21) Appl. No.: 18/350,196

(22) Filed: Jul. 11, 2023

Related U.S. Application Data
(60) Provisional application No. 63/388,002, filed on Jul. 11, 2022.

(51) Int. Cl. A45F 3/14; H04R 1/02; H05K 5/00; F16M 13/04

(52) U.S. Cl. CPC A45F 3/14; H04R 1/025; H05K 5/0086; F16M 13/04; A45F 2003/146

(57) ABSTRACT

A mobile entertainment system that is portable and can be easily carried by a user for playing audio while providing a DJ-like musical experience. The apparatus can be positioned around the torso of the user supported by shoulders and waist. The apparatus includes a frame to which different components can be mounted. Over the front mid-portion of the frame can be mounted a DJ console. The user can enter into the frame between the console and the rear side of the frame such that facing the console. A harness, which can be worn like a backpack, can be coupled to the frame and allow carrying the apparatus hands-free. The apparatus includes a DJ console, Sub-woofer, DJ lights, speakers, amplifiers, and the like equipment common in a DJs system. A specially designed sub-woofer housing is coupled on the rear side of the frame.

### CROSS-REFERENCE TO RELATED APPLICATIONS

This application claims priority from a U.S. Provisional Patent Application Ser. No. 63/388,002 filed on Jul. 11, 2022, the disclosure of which is incorporated herein by reference in its entirety.

### FIELD OF INVENTION

The present invention relates to a mobile entertainment apparatus, and more particularly, the present invention relates to a mobile music entertainment apparatus that can be supported hands-free over a torso of a person.

### BACKGROUND

A disc jockey, also commonly abbreviated as DJs, is a person who plays recorded audio for an audience. DJs use a wide range of technical equipment as an entertainment system to create a high-energy musical experience for their audience. Various technical equipment includes controllers, turntables, lights, multiple speakers, amplifiers, microphones, and the like. The whole setup is stationary and quite bulky, which limits the mobility of the DJs. Because of the stationery set-up, the DJs remain at some distance from the audience and interact with the audience from a distance. This limits the opportunities that DJs may have for interaction with audiences and DJs' ability to move towards gathered crowds. This is a major limitation of the present fixed setup. Moreover, the fixed setup requires a lot of time and labor for installation. This limits the utility of such DJs systems in fixed locations and the costs are also high. DJs are played in many locations, such as parties, get-togethers, entertainment venues, theme parks, resorts, hotels, sports venues, events, and the like. However, a fixed DJ setup is not practical for many of the locations due to various factors, such as cost, place, weather, and the like.

Thus, a need is appreciated for a novel mobile entertainment apparatus that overcomes the aforesaid drawbacks and limitations with a fixed DJs setup.

### SUMMARY OF THE INVENTION

The following presents a simplified summary of one or more embodiments of the present invention in order to provide a basic understanding of such embodiments. This summary is not an extensive overview of all contemplated embodiments and is intended to neither identify key or critical elements of all embodiments nor delineate the scope of any or all embodiments. Its sole purpose is to present some concepts of one or more embodiments in a simplified form as a prelude to the more detailed description that is presented later.

The principal object of the present invention is therefore directed to a mobile entertainment apparatus for DJs that overcomes the limitations with a fixed setup.

It is another object of the present invention that the mobile entertainment apparatus provides an experience similar to a fixed DJs setup.

It is still another object of the present invention that a person can comfortably carry the mobile entertainment apparatus.

It is a further object of the present invention that most of the technical equipment of a fixed DJs setup can be incorporated.

It is still a further object of the present invention that the different types of equipment of the mobile entertainment apparatus can be easily operated by the user.

It is yet a further object of the present invention that the mobile entertainment apparatus is light in weight.

In one aspect, disclosed is a mobile entertainment system comprising a frame, the frame has a front side, a rear side, a left side, a right side, a top side, and a bottom side, the frame is configured to be positioned around a torso of a user; a harness configured to be worn over the torso of the user, wherein the frame is suspended from the harness. The frame comprises a front left vertical member, a rear left vertical member, a front right vertical member, and a rear right vertical member, a left horizontal member extends between the front left vertical member and the rear left vertical member, a right horizontal member extends between the front right vertical member and the rear right vertical member, a front horizontal member extends between the front left vertical member and the front right vertical member, a rear horizontal member extends between the rear left vertical member and the rear right vertical member.

On one aspect, the mobile entertainment system further comprises a sub-woofer enclosure, the sub-woofer enclosure coupled on the rear side of the frame. The mobile entertainment system further comprises a battery positioned over the sub-woofer enclosure.

In one aspect, the mobile entertainment system further comprises one or more speakers. The mobile entertainment system further comprises a media playback device, a turntable, an amplifier, and an audio mixer. A length and a width of the sub-woofer enclosure corresponds to the rear side of the frame.

In one aspect, the harness comprises a rigid support member of an elongated profile having an upper portion and a lower portion; a shoulder strap coupled to the upper portion of the rigid support member, the shoulder strap configured to be secured around shoulders and chest of the user; and a waist strap coupled to the lower portion of the rigid support member, the waist strap configured to be secured around waist of the user. The rigid support member is coupled to the frame using a plurality of coupling straps for suspending the frame.

### BRIEF DESCRIPTION OF THE DRAWINGS

The accompanying figures, which are incorporated herein, form part of the specification and illustrate embodiments of the present invention. Together with the description, the figures further explain the principles of the present invention and enable a person skilled in the relevant arts to make and use the invention.

FIG. 1 is a side view of a mobile entertainment apparatus, according to an exemplary embodiment of the present invention.

FIG. 2 is a front view of the mobile entertainment apparatus, according to an exemplary embodiment of the present invention.

FIG. 3 is a side perspective view of the mobile entertainment apparatus shown without front panel and side panels, according to an exemplary embodiment of the present invention.

FIG. 4 is an enlarged rear and side perspective view showing a subwoofer housing of the mobile entertainment apparatus, according to an exemplary embodiment of the present invention.

FIG. 5 shows a harness of the mobile entertainment apparatus, according to an exemplary embodiment of the present invention.

### DETAILED DESCRIPTION

Subject matter will now be described more fully hereinafter. Subject matter may, however, be embodied in a variety of different forms and, therefore, covered or claimed subject matter is intended to be construed as not being limited to any exemplary embodiments set forth herein; exemplary embodiments are provided merely to be illustrative. Likewise, reasonably broad scope for claimed or covered subject matter is intended. Among other things, for example, the subject matter may be embodied as apparatus and methods of use thereof. The following detailed description is, therefore, not intended to be taken in a limiting sense.

The word “exemplary” is used herein to mean “serving as an example, instance, or illustration.” Any embodiment described herein as “exemplary” is not necessarily to be construed as preferred or advantageous over other embodiments. Likewise, the term “embodiments of the present invention” does not require that all embodiments of the invention include the discussed feature, advantage, or mode of operation.

The terminology used herein is to describe particular embodiments only and is not intended to be limiting to embodiments of the invention. As used herein, the singular forms “a”, “an”, and “the” are intended to include the plural forms as well, unless the context indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The following detailed description includes the best currently contemplated mode or modes of carrying out exemplary embodiments of the invention. The description is not to be taken in a limiting sense but is made merely to illustrate the general principles of the invention since the scope of the invention will be best defined by the allowed claims of any resulting patent.

The following detailed description is described with reference to the drawings, wherein reference numerals are used to refer to like elements throughout. In the following description, for purposes of explanation, specific details may be set forth in order to provide a thorough understanding of the subject innovation. It may be evident, however, that the claimed subject matter may be practiced without these specific details. In other instances, well-known structures and apparatus are shown in block diagram form to facilitate describing the subject innovation. Moreover, the drawings may not be to scale.

Disclosed is a mobile entertainment apparatus that can be used by disc jockeys, entertainers, and the like users to present a high-energy interactive musical experience to the users. The term “user” herein refers to a person playing or willing to play the disclosed apparatus. The mobile entertainment apparatus can be carried by a user by supporting the same over the torso of the user. The user carrying the disclosed mobile entertainment apparatus can easily walk around and play equipment of the apparatus. The different types of equipment of the disclosed mobile entertainment apparatus are within reach of the user and can be easily operated by the free hands of the user. The apparatus is light enough to be worn and supported by the torso of the user and carried by the user. The apparatus can include professional-grade controllers/decks; turntables, media playback devices, amplifiers, and mixers, DJs lights, speakers, and like equipment commonly used by DJs.

Preferably, the disclosed apparatus can include wireless connectivity for connecting to different equipment of the disclosed apparatus and to connect with external equipment. For example, the disclosed apparatus can wirelessly connect to a fixed audio installation so that the apparatus can simultaneously control and broadcast media from both the apparatus and other fixed or mobile external equipment and thereby use the functionality of external systems without any limitations. The apparatus can be wirelessly connected to a fixed DJ installation to allow the DJ to periodically leave the fixed installation and move through the venue while simultaneously controlling and broadcasting the media from both locations. The user while playing the disclosed apparatus can walk around playing the apparatus and interacting with the audience, move among multiple locations to where crowds have gathered, or gather a crowd, and engage in performance applications (such as line dancing, conga lines, contests, etc.) in ways not possible with a fixed musical and light instrument set-up.

Advantageously, the disclosed apparatus is versatile by having different equipment that can be interchangeably used. The apparatus can interchangeably mount certain equipment, such as speakers, mixer consoles, and the like. The disclosed apparatus can be versatile by allowing the user to customize the apparatus, such as by modifying sound settings and light settings for a desired audio and visual experience. The user can change equipment from the disclosed apparatus or can add a new one. It is also envisioned that the disclosed apparatus can combine newly created and existing components in a novel and unique way, and the result is a versatile and entertaining performance product that is portable and could be easily carried to different sites and occasions.

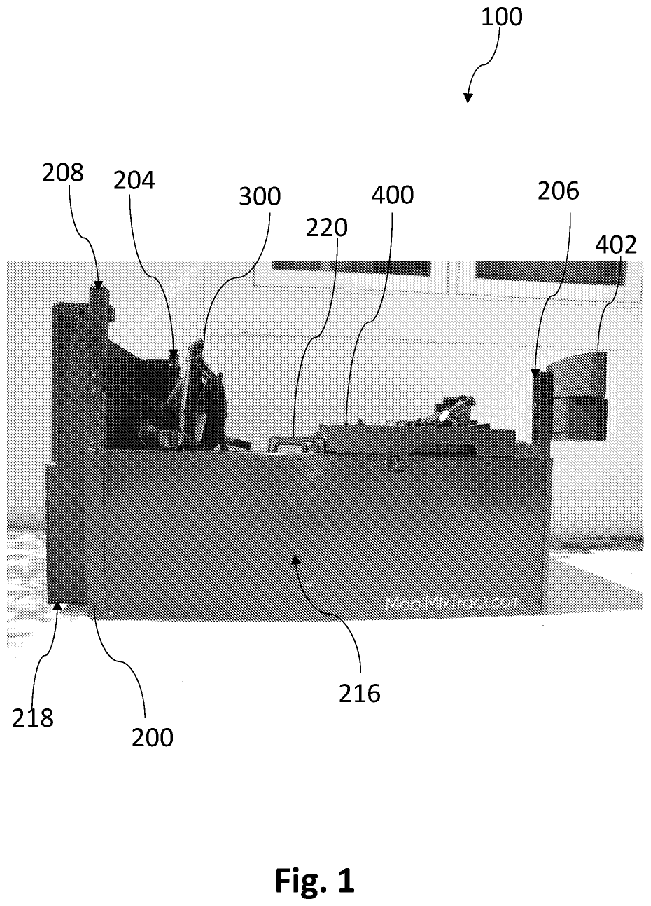

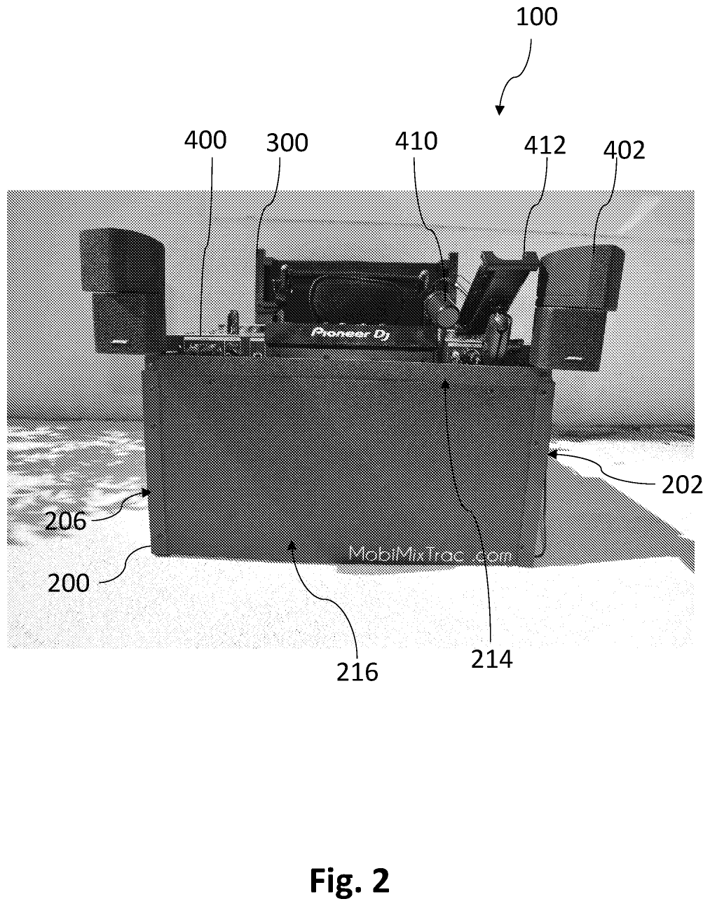

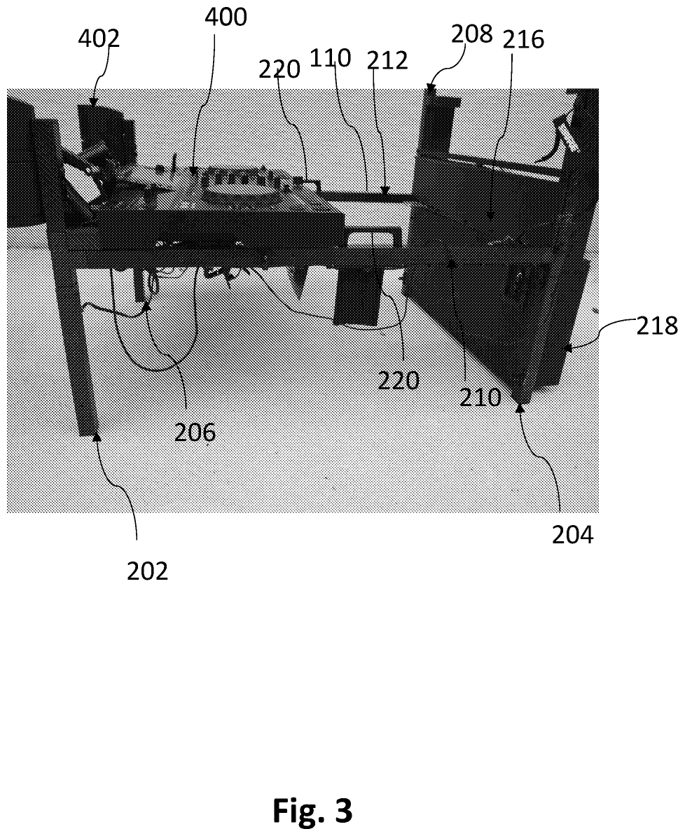

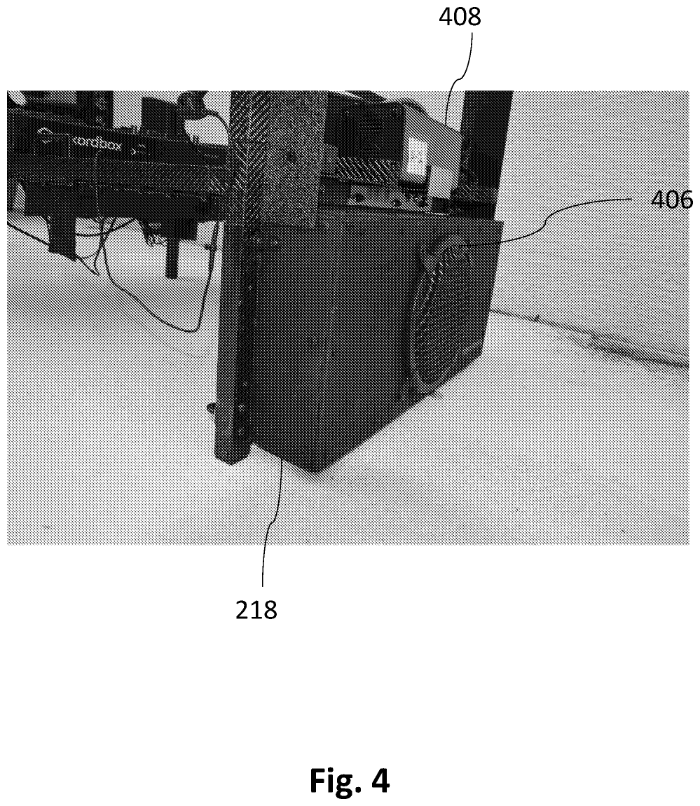

Referring to FIGS. 1-2 which shows a side view and a front view of the disclosed mobile entertainment system 100. The mobile entertainment system 100 shown in the drawing is rectangular in shape. The apparatus 100 includes a frame 200 which is more clearly shown in FIGS. 3 and 4. The frame includes four vertical members that form the four corners of the apparatus. The vertical members can be of an elongated tubular profile of which the lengths may be optionally adjustable. For example, the vertical members can be made from telescoping tubes that allow the lengths of the tubes to be increased or decreased. Alternative to the telescoping tubes, tubular extensions can be coupled at either end of the vertical members to increase the effective lengths thereof. The extensions can be coupled using suitable brackets and fasteners. Or the extensions can be coupled permanently, for example using welding. It is to be noted that the lengths of the four vertical members of the disclosed frame can be the same or different, and any such variations in the lengths of the four vertical members are within the scope of the present invention. The frame can also act as a stand with the four vertical members forming the legs of the stand, so that the disclosed apparatus can be placed on a flat surface, such as on a floor or a tabletop. One or more of the electronic units/equipment of the disclosed apparatus can be coupled to one or more of the vertical members. It is to be noted that drawings illustrate a rectangular frame for illustration only, the shape of the frame, however, can be modified without departing from the scope of the present invention. For example, the frame can be triangular, oval, or polygonal in shape. FIG. 3 shows a front left vertical member 202, a rear left vertical member 204, a front right vertical member 206, and a rear right vertical member 208.

The frame 200 further includes horizontal members, also referred to herein as side members, that transversely extend between adjacent vertical members. For example, the frame can have a front side, a rear side, a left side, and a right side. A left horizontal member 210 can extend between the front left vertical member 202 and the rear left vertical member 204, which forms the left side of the frame. Similarly, the frame has a right horizontal member 212, a front horizontal member 214 (visible in FIG. 2), and a rear horizontal member 216. Each side of the frame can have more than one horizontal member, wherein one or more sides of the frame can have a different number of horizontal members. More than one horizontal member can be added on either side depending upon the desired utility. The horizontal members on each side of the frame can run parallel and spaced apart from each other. The frame can be made from any durable and rigid material, however, to keep the weight of the apparatus lighter, preferably, the frame can be made from lightweight and sturdy materials, such as carbon fiber, Aluminum, and the like. The frame may be wide enough so that the apparatus can be worn by a user around the waist and buttocks. The frame can be passed through the head or the legs of the user and retained around the waist and buttocks of the user.

The apparatus may further include side panels 216 on the front side, the rear side, the left side, and the right side thereof. The panels can provide a supportive surface for fasteners, clips, electronic units, and the like. The panels can also hide the wires, equipment, and the like providing an aesthetic appearance to the disclosed apparatus. The panels can be made in any color for aesthetic appeal. Moreover, suitable designs can be applied to either or all the panels as desired by the user. The panels on the front and both sides can be made approximately twelve inches high and can feature branding or advertisements, products, venue logos, sports team colors, and/or the like. Moreover, the panels can be changeable to accommodate different venues or events.

On the rear side of the frame is shown a sub-woofer enclosure 218 coupled to the rear side of the frame. FIG. 3 shows a rear and side perspective view of sub-woofer enclosure 218. FIG. 4 shows a rear and side view of the sub-woofer enclosure 218. The sub-woofer enclosure 218 may be thinner in width to keep the length of the apparatus smaller and the apparatus to have more stability when carried by the user. Moreover, the sub-woofer enclosure 218 has been designed to keep the overall weight of the apparatus low. The unique dimensions of the sub-woofer enclosure 218, as shown in the drawings, help to achieve both lighter weight and portability. The sub-woofer enclosure 218 can have a thin wood panel on the rear exposed side and a thinner wood panel on the opposite side that may move air in concert with the sub-woofer speaker, improving the efficiency of the lightweight enclosure.

The left horizontal member and the right horizontal member can also be provided with handles 220 that can be grabbed in the hands by the user for handling and maneuvering the disclosed apparatus. The handles can be welded to the horizontal members or coupled using suitable fasteners. The handles may also be provided with a suitable grip for the comfort of the user and aid in fitting and decoupling the user from the harness. The frame can also be provided with suitable clips, brackets, clamps, and the like for attaching different components of the disclosed apparatus.

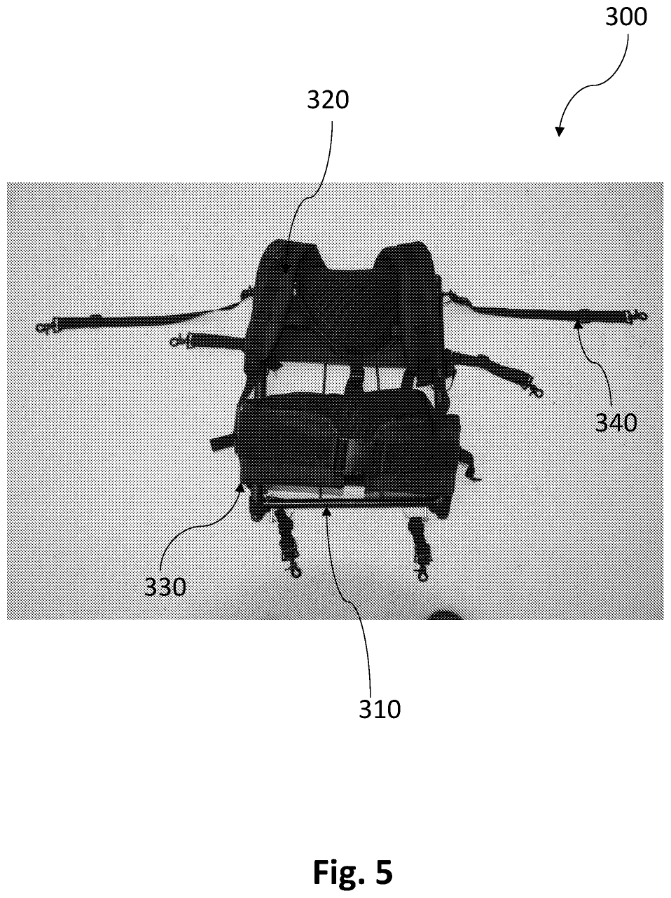

Referring to FIG. 5 shows a harness 300 of the disclosed apparatus 100 that can be worn around the shoulders and waist of the user. The harness includes a rigid support member 310 that may be of an elongated profile having an upper portion and a lower portion. The rigid support member shown in the drawings is rectangular, however, the shape can be varied without departing from the scope of the present invention. For example, the rigid support member can be rectangular with rounded corners or elliptical. The harness can include a shoulder strap 320 coupled to the upper portion of the rigid support member that secures around the shoulder and chest of the user. A waist strap 330 is coupled to the lower portion of the rigid support member and can be secured around the waist of the user. The shoulder strap and the waist strap can be wide enough for a comfortable fit so that the weight can be evenly distributed and does not dig into the skin. The shoulder strap and the waist strap can have suitable fastening means, such as interlocking brackets or hook and loop fasteners. The shoulder strap and the waist strap can also have a good number of cushioning pads for comfort and to prevent the straps from digging into the user's skin. The harness can be worn on the back of the user with the shoulder strap and the waist strap tightened securely.

The harness can be secured to the frame using coupling straps that extend from the rigid support member. FIG. 5 shows multiple coupling straps 340 that extend from both the left and right sides of the rigid support member. The free ends of the coupling straps can have detachable connectors that fasten to the frame. The coupling straps can be strategically placed on both sides of the rigid support member to provide stability to the apparatus when worn by the user. The coupling straps may also allow biasing of the front portion of the apparatus slightly up compared to the rear portion depending on the user's preference. Each of the coupling straps can include length adjustment means, such as a slider. The lengths of the coupling straps can be adjusted for pulling the apparatus against the user's back and away from the user's stomach for comfort, stability, and ease of use while performing. In use, the harness can be first worn by the user and then the harness can be coupled to the frame positioned around the torso of the user. Or the apparatus with harness coupled to the frame can be lifted around the torso of the user, and then the user can wear the harness. Both the hands of the user may remain free and the apparatus is supported only by the torso of the user. The various controls of the apparatus are within the reach of the hands and can be operated by the user easily and comfortably. Moreover, the controls, buttons, and knobs can be provided at the waist level which allows the user to roam and play easily and conveniently. It is understood that suitable rings can be welded to the frame to which connectors of the coupling straps can be secured. Any other method for securing the connectors of the coupling straps to the frame is within the scope of the present invention. Also, the number of coupling straps can be varied without departing from the scope of the present invention. The coupling straps can be provided on any side of the rigid support member, such as the left, right, top, and bottom sides. Also, the number of coupling straps on opposite sides can be the same or different. The coupling straps can be interchangeably used, so that the user can change both the number and positions of the coupling straps on the rigid support member.

In certain implementations, the harness can resemble an adventure backpack with padded straps. As explained above, the number and positions of the coupling straps can be varied, the harness may include at least four unique and calculated points of connections—two to the user's front and two to the user's back. The harness is adjustable for the size and comfort of the user. The harness is designed to distribute the weight of the apparatus in a balanced manner between the user's shoulders and hips, allows the user to have both hands free at all times, and can use leverage by adjusting the length of the coupling straps to properly position the user within the frame space between the console, the side horizontal members, and the rear horizontal member of the frame. The leverage at the rear connections can be used to stabilize and balance the apparatus weight and is designed to cause the entire apparatus to securely move or dance in concert with the user's movements.

The frame members including the vertical members, the horizontal members, and the panels can be provided with clips, brackets, clamps, and the like for securing different components of the apparatus. FIG. 3 shows a console unit 400 secured to the front of the frame. The console unit can be supported on the front horizontal member and front portions of the left and right horizontal members. The space between the console and the back side of the apparatus i.e., the rear horizontal member, is where a user can enter, wherein the user faces the front side of the apparatus. The user can operate various controls on the console unit. The console can be used to play music by the user. The user can play around with different controls, such as buttons, knobs, and faders to mix and edit the music. A suitable number of speakers 402 can be mounted to the frame. For example, the speakers can be mounted to the top portions of the vertical members. More than one speaker can be mounted to each vertical member. The speaker includes speaker housing that has a bracket using which the speaker can be mounted. The speakers can include components known to a skilled person for use in speakers for playing audio and music.

A sub-woofer 406 can be mounted in the sub-woofer housing. More than one sub-woofer can be provided, and any number of sub-woofers are within the scope of the present inventions. Different components including the console, amplifier, speakers, sub-woofer, and the like can be connected through wires and wirelessly as and when feasible. The wires can be made to run inside the horizontal and vertical hollow frame members or along the vertical members and the horizontal members around the frame. The wires can be secured using clips and ties in an organized manner to prevent any clutter of wires.

The disclosed apparatus can be powered by a portable battery 408 that may be rechargeable. Examples of rechargeable batteries include lithium-ion batteries. Disposable batteries can also be used instead of rechargeable batteries. It is understood that more than one battery can be used, and each battery can include multiple battery cells. The battery may be coupled to the frame using suitable battery housing. For example, the battery can be encased within the sub-woofer housing or placed above the sub-woofer housing. The different components of the disclosed apparatus may be so arranged to have uniform weights on opposite sides of the apparatus.

DJ lights can be coupled to vertical members, horizontal members, and/or panels. Different kinds of lights can be used to enhance the visual experience, such as different color LEDs can be used around the apparatus. It is understood, however, that various electronic components may be optional, such as the user can install lights if desired. A spotlight 410 can also be used to highlight the user's appearance in the crowd. The media can be played by a smartphone and the disclosed apparatus can include a smartphone holder 412 facing the rear side of the apparatus.

The different components of the disclosed apparatus, such as the console, lights, and speakers can be designed to be light in weight yet include most of the features of a standard DJs system. Amplifiers can be used for audio amplification and the amplifier can be coupled to the frame and speakers can be connected to the amplifier using aux cables. The sub-woofer housing has been designed to add the low-end punch and full-spectrum sound associated with professional DJ applications. A custom and uniquely shaped subwoofer housing has been manufactured from lightweight reinforced wood panels. This reduces the weight of the sub-woofer significantly and at the same time provides an enhanced audio experience. This design of the sub-woofer may be a critical and essential feature to keep the overall weight of the disclosed apparatus low.

A dynamic microphone headset can also be provided, through the DJ controller's mixer, to supply public address audio for audience interaction. It is important, that the different components of the disclosed apparatus are arranged such that the apparatus has a balanced weight. The placement of the DJ's console on the front side is essential, and based on this position of the console, the other components can be arranged. For example, the weight of the apparatus can be balanced by the placement of the main speakers at the extreme front, the DJs console in the mid-front, and the subwoofer and the battery components at the rear.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention as claimed.

What is claimed is:

1. A mobile entertainment system comprising:
a frame, the frame has a front side, a rear side, a left side, a right side, a top side, and a bottom side, the frame is configured to be positioned around a torso of a user; and
a harness configured to be worn over the torso of the user, wherein the frame is suspended from the harness.

2. The mobile entertainment system of claim 1, wherein the frame comprises a front left vertical member, a rear left vertical member, a front right vertical member, and a rear right vertical member, a left horizontal member extends between the front left vertical member and the rear left vertical member, a right horizontal member extends between the front right vertical member and the rear right vertical member, a front horizontal member extends between the front left vertical member and the front right vertical member, a rear horizontal member extends between the rear left vertical member and the rear right vertical member.

3. The mobile entertainment system of claim 1, wherein the mobile entertainment system further comprises a sub-woofer enclosure, the sub-woofer enclosure coupled on the rear side of the frame.

4. The mobile entertainment system of claim 3, wherein the mobile entertainment system further comprises a battery positioned over the sub-woofer enclosure.

5. The mobile entertainment system of claim 1, wherein the mobile entertainment system further comprises one or more speakers.

6. The mobile entertainment system of claim 1, wherein the mobile entertainment system further comprises a media playback device, a turntable, an amplifier, and an audio mixer.

7. The mobile entertainment system of claim 1, wherein the harness comprises:
a rigid support member of an elongated profile having an upper portion and a lower portion;
a shoulder strap coupled to the upper portion of the rigid support member, the shoulder strap configured to be secured around shoulders and chest of the user; and
a waist strap coupled to the lower portion of the rigid support member, the waist strap configured to be secured around waist of the user.

8. The mobile entertainment system of claim 7, wherein the rigid support member is coupled to the frame using a plurality of coupling straps for suspending the frame.

9. The mobile entertainment system of claim 3, wherein a length and a width of the sub-woofer enclosure corresponds to the rear side of the frame.

10. A method for providing a DJ like musical experience to audience, the method comprising:
providing a mobile entertainment system comprising:
a frame, the frame has a front side, a rear side, a left side, a right side, a top side, and a bottom side, the frame is configured to be positioned around a torso of a user, and
a harness configured to be worn over the torso of the user, wherein the frame is suspended from the harness;
wearing the harness over back of the user;
placing the frame around the torso of the user, wherein the frame is passed through legs or head of the user; and
coupling the harness to the frame.

11. The method of claim 10, wherein the frame comprises a front left vertical member, a rear left vertical member, a front right vertical member, and a rear right vertical member, a left horizontal member extends between the front left vertical member and the rear left vertical member, a right horizontal member extends between the front right vertical member and the rear right vertical member, a front horizontal member extends between the front left vertical member and the front right vertical member, a rear horizontal member extends between the rear left vertical member and the rear right vertical member.

12. The method of claim 10, wherein the mobile entertainment system further comprises a sub-woofer enclosure, the sub-woofer enclosure coupled on the rear side of the frame.

13. The method of claim 12, wherein the mobile entertainment system further comprises a battery positioned over the sub-woofer enclosure.

14. The method of claim 10, wherein the mobile entertainment system further comprises one or more speakers.

15. The method of claim 10, wherein the mobile entertainment system further comprises a media playback device, a turntable, an amplifier, and an audio mixer.

16. The method of claim 10, wherein the harness comprises:
a rigid support member of an elongated profile having an upper portion and a lower portion;
a shoulder strap coupled to the upper portion of the rigid support member, the shoulder strap configured to be secured around shoulders and chest of the user; and
a waist strap coupled to the lower portion of the rigid support member, the waist strap configured to be secured around waist of the user.

17. The method of claim 16, wherein the rigid support member is coupled to the frame using a plurality of coupling straps for suspending the frame.

18. The method of claim 13 wherein a length and a width of the sub-woofer enclosure corresponds to the rear side of the frame.
